(19) United States
(12) Patent Application Publication
(10) Pub. No.: US 2010/0061066 A1
(43) Pub. Date: Mar. 11, 2010

(54) CIRCUIT BORAD SHIELD

(75) Inventors: ZHENG-YONG GUAN, Shenzhen City (CN); TING DONG, Shenzhen City (CN); CHENG-HAO CHOU, Tu-Cheng (TW); GAO-HUI TANG, Shenzhen City (CN); WEN-HSIANG LU, Tu-Cheng (TW); WEN-HSIEN HUANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/434,677

(22) Filed: May 3, 2009

(30) Foreign Application Priority Data
Sep. 5, 2008 (CN) 200810304388.9

(51) Int. Cl. H05K 5/00

(52) U.S. Cl. 361/752

(57) ABSTRACT

A circuit board shield includes a cover, a plurality of connecting pins and a plurality of resilient conductive pins extended downwardly from the cover. The connecting pins are able to be twisted, and comprise hooks. The shield can be mounted to a circuit board without soldering.

### BACKGROUND

1. Technical Field

The present disclosure relates to a shield.

2. Description of Related Art

Shields, when used on circuit boards, are usually connected to the circuit boards by soldering. Yet, the circuit boards usually carry many components thereon. Soldering is inconvenient and may destroy the components.

What is needed is a shield which can be mounted to a circuit board without soldering.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic, isometric view of a shield according to an exemplary embodiment.

FIG. 2 is an isometric, cutaway view showing the shield of FIG. 1 being mounted on a printed circuit board.

FIG. 3 is a schematic, isometric view of the shield and the printed circuit board of FIG. 2, showing from another angle.

### DETAILED DESCRIPTION

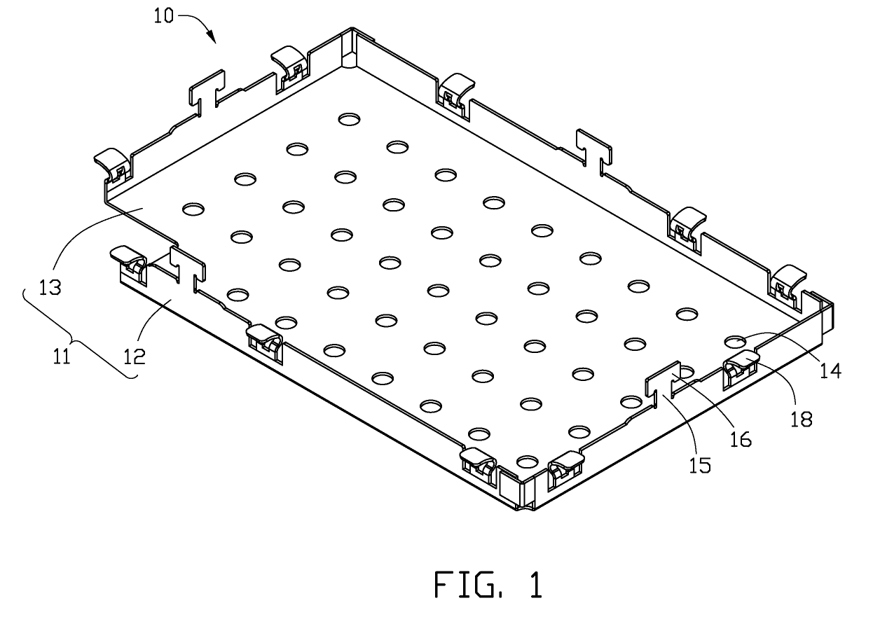

Referring to FIG. 1, a shield 10 according to an exemplary embodiment is disclosed. The shield 10 includes a cover 11. The cover 11 includes a rectangular top part 12 and a skirt edge 13 extended downwardly from the top part 12. The top part 12 defines a plurality of heat dissipation holes 14.

A plurality of T shaped connecting pins 15 and L shaped conductive pins 18 are extended downwardly from the skirt edge 13. Each of the connecting pins 15 includes a hook 16. The connecting pins 15 are thin for being twisted. Each of the conductive pins 18 is resilient.

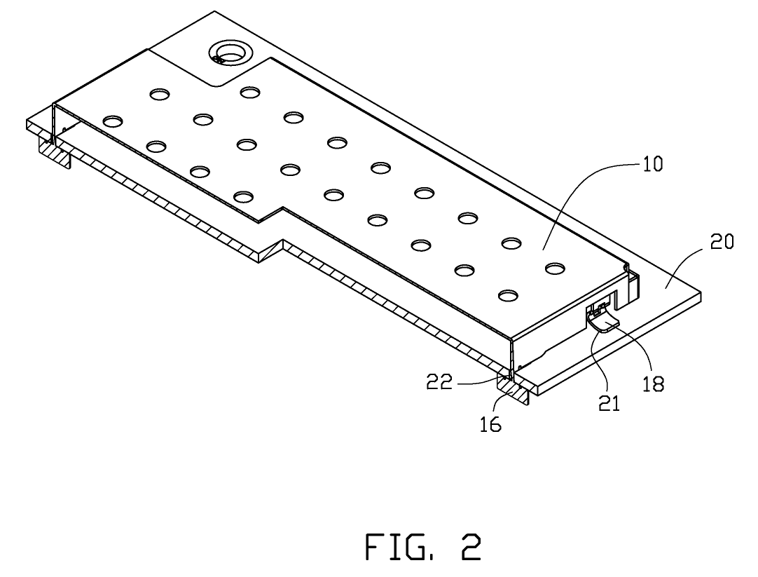

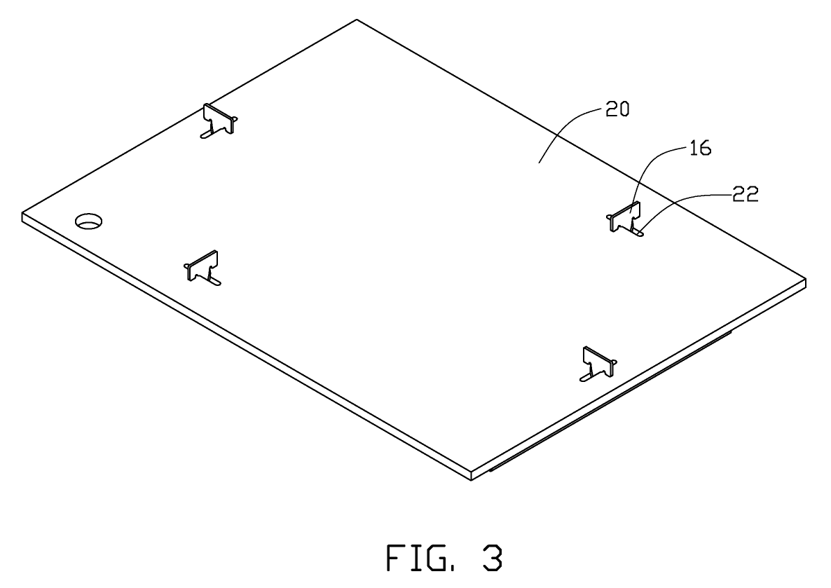

Referring also to FIGS. 2 and 3, a printed circuit board 20 defines slots 22, corresponding the connecting pins 15, and conductive pads 21 thereof.

To assemble, the connecting pins 15 are extended through the slots 22 of the printed circuit board 20, then the connecting pins 15 are twisted and the hooks 16 clasp the bottom surface of the printed circuit board 20, thus to mount the shield 10 on the printed circuit board 20. The conductive pins 18 resiliently press against the conductive pads 21 of the printed circuit board 20, thus to enhance shield effect.

Moreover, it is to be understood that the invention may be embodied in other forms without departing from the spirit thereof. Thus, the present examples and embodiments are to be considered in all respects as illustrative and not restrictive, and the invention is not to be limited to the details given herein.

What is claimed is:

1. A circuit board shield comprising:
a cover;
a plurality of connecting pins extended downwardly from the cover, wherein each of the connecting pins is capable of being twisted, and comprises a hook; and
a plurality of resilient conductive pins extended downwardly from the cover.

2. The circuit board shield of claim 1, wherein the connecting pins are T shaped.

3. The circuit board shield of claim 1, wherein the resilient conductive pins are L shaped.

4. The circuit board shield of claim 1, wherein the cover comprises a top part and a skirt edge extended downwardly from the top part.

5. The circuit board shield of claim 4, wherein the connecting pins and conductive pins are extended downwardly from the skirt edge.

6. The circuit board shield of claim 4, wherein the top part defines a plurality of heat dissipation holes.
